(19) United States
(12) Patent Application Publication
(10) Pub. No.: US 2025/0151433 A1
(43) Pub. Date: May 8, 2025

(54) SEMICONDUCTOR STRUCTURES AND METHODS OF FORMING THE SAME

(71) Applicant: Taiwan Semiconductor Manufacturing Company, Ltd., Hsinchu (TW)

(72) Inventors: Cheng-Ying HO, Chiayi County (TW); Kai-Chun HSU, Yonghe City (TW); Wen-De WANG, Chiayi County (TW); Yuh HUANG, Hsinchu County (TW); Cheng-Yu HSIEH, Tainan City (TW); Hung-Yu WANG, Keelung City (TW); Jen-Cheng LIU, Hsin-Chu City (TW)

(21) Appl. No.: 18/501,332

(22) Filed: Nov. 3, 2023

(51) Int. Cl. H01L 27/146

(52) U.S. Cl. CPC H10F 39/8053; H10F 39/024; H10F 39/182; H10F 39/186

(57) ABSTRACT

A pixel array that includes some pixels with high absorption (HA) structures and other pixels without HA structures exhibits increased dynamic range for near infrared (NIR) light. Additionally, the pixel array is a uniform array of photodiodes and thus does not exhibit current leakage that would have been caused by irregular isolation structures. Additionally, the pixel array may further a lateral overflow integration capacitor to further increase the dynamic range for NIR light.

### BACKGROUND

Complementary metal oxide semiconductor (CMOS) image sensors utilize light-sensitive CMOS circuitry to convert light energy into electrical energy. The light-sensitive CMOS circuitry may include a photodiode formed in a silicon substrate. As the photodiode is exposed to light, an electrical charge is induced in the photodiode (referred to as a photocurrent). The photodiode may be coupled to a switching transistor, which is used to sample the charge of the photodiode. Colors may be determined by placing filters over the light-sensitive CMOS circuitry.

Light received by pixel sensors of a CMOS image sensor is often based on the three primary colors: red, green, and blue (R, G, B). Pixel sensors that sense light for each color can be defined through the use of a color filter that allows the light wavelength for a particular color to pass into a photodiode. Some pixel sensors may include a near infrared (NIR) pass filter, which blocks visible light and passes NIR light through to the photodiode.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagram of an example pixel array in which systems and/or methods described herein may be implemented.

FIG. 2A is a diagram of an example semiconductor structure described herein.

FIG. 2B is a diagram of an example data graph described herein.

FIGS. 3A-3C are diagrams of example pixel arrays described herein.

FIGS. 4A-4J are diagrams of an example implementation described herein.

FIG. 5 is a flowchart of an example process associated with forming a semiconductor structure described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The dynamic range of an image sensor is based on a capacity of the sensor (for example, measured in electrons) relative to noise in the image sensor. The range is generally expressed in decibels (dB). In order to increase the dynamic range, an image sensor may include a pixel array with large photodiodes (LPDs) and small photodiodes (SPDs). The LPDs and SPDs have different capture rates. As a result, exposure time is increased by combining LPDs and SPDs and the capacity of the sensor is increased, which results in a larger dynamic range.

However, because LPDs and SPDs are different sizes, the pixel array is somewhat irregular, which reduces efficacy of isolation structures (for example, shallow trench isolations (STIs) and backside deep trench isolations (BDTIs)). As a result, current leakage is increased, particularly in portions of the pixel array with smaller isolation structures. Additionally, combining LPDs and SPDs does not increase the dynamic range of the pixel array for near infrared (NIR) light.

Some implementations described herein provide techniques and apparatuses for forming a pixel array that includes some pixels with high absorption (HA) structures and other pixels without HA structures. As a result, the pixel array is a uniform array of photodiodes but with increased dynamic range for NIR light and without increased current leakage that is caused by irregular isolation structures. Additionally, the pixel array may further include a lateral overflow integration capacitor (LOFIC) to further increase the dynamic range for NIR light.

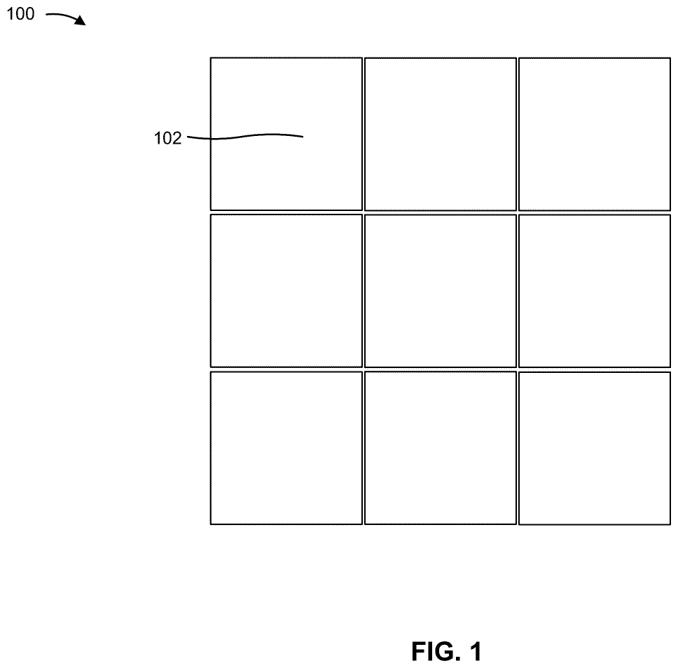

FIG. 1 is a diagram of an example pixel array 100 (or a portion thereof) described herein. The pixel array 100 may be included in an image sensor, such as a complementary metal oxide semiconductor (CMOS) image sensor, a back side illumination (BSI) CMOS image sensor, or another type of image sensor.

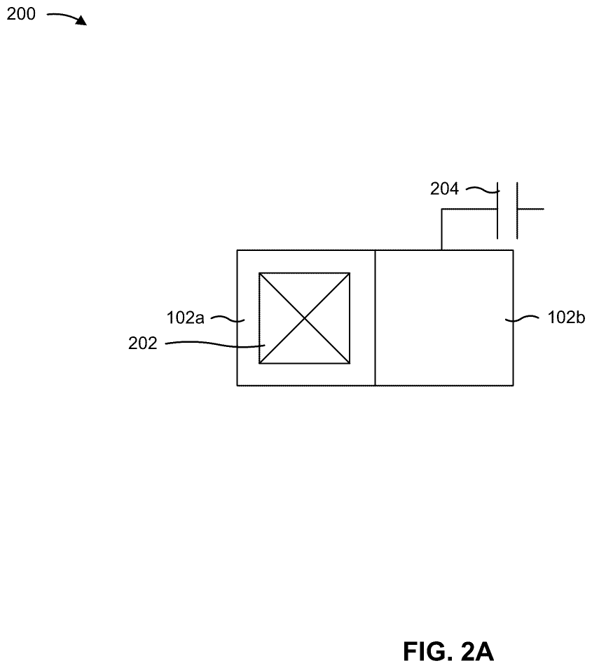

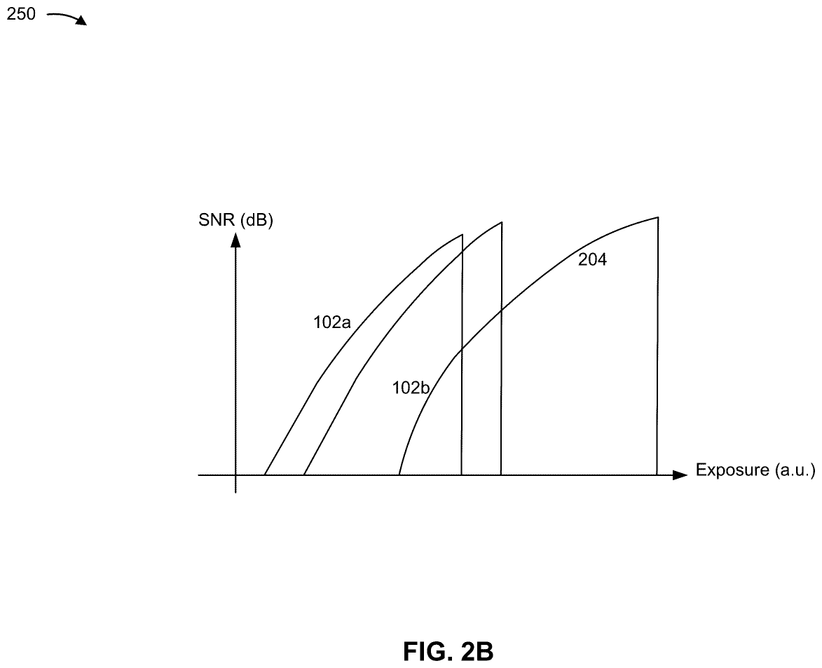

FIG. 1 shows a top-down view of the pixel array 100. As shown in FIG. 1, the pixel array 100 may include a plurality of pixel sensors 102. As further shown in FIG. 1, the pixel sensors 102 may be arranged in a grid. In some implementations, the pixel sensors 102 are square-shaped (as shown in the example in FIG. 2). In some implementations, the pixel sensors 102 include other shapes such as circle shapes, octagon shapes, diamond shapes, and/or other shapes.

The pixel sensors 102 may be configured to sense and/or accumulate incident light (e.g., light directed toward the pixel array 100). For example, a pixel sensor 102 may absorb and accumulate photons of the incident light in a photodiode. The accumulation of photons in the photodiode may generate a charge representing the intensity or brightness of the incident light (e.g., a greater amount of charge may correspond to a greater intensity or brightness, and a lower amount of charge may correspond to a lower intensity or brightness).

The pixel array 100 may be electrically connected to a back-end-of-line (BEOL) metallization stack (not shown) of the image sensor. The BEOL metallization stack may electrically connect the pixel array 100 to control circuitry that may be used to measure the accumulation of incident light in the pixel sensors 102 and convert the measurements to an electrical signal.

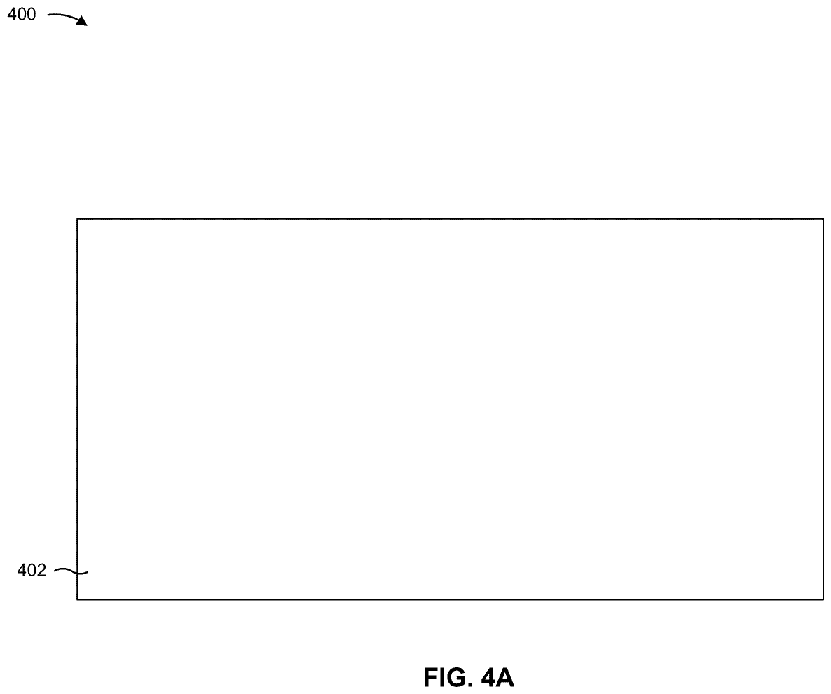

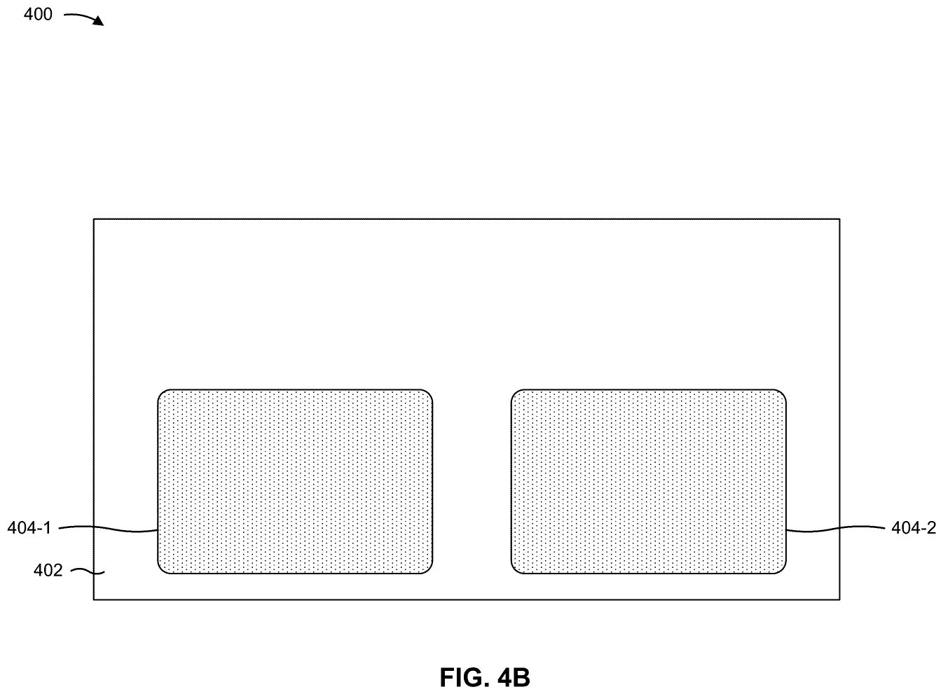

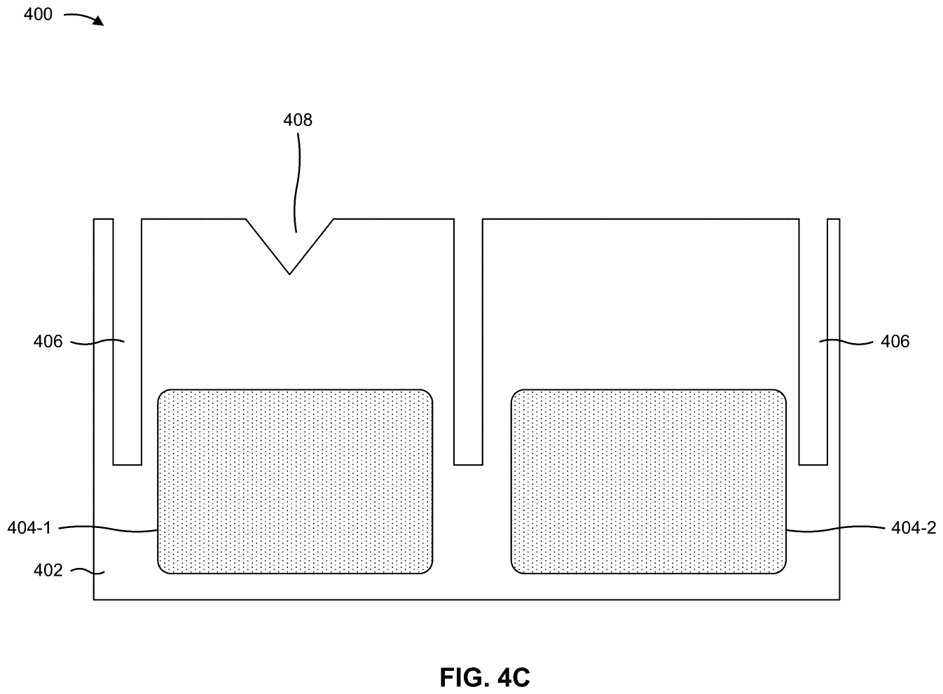

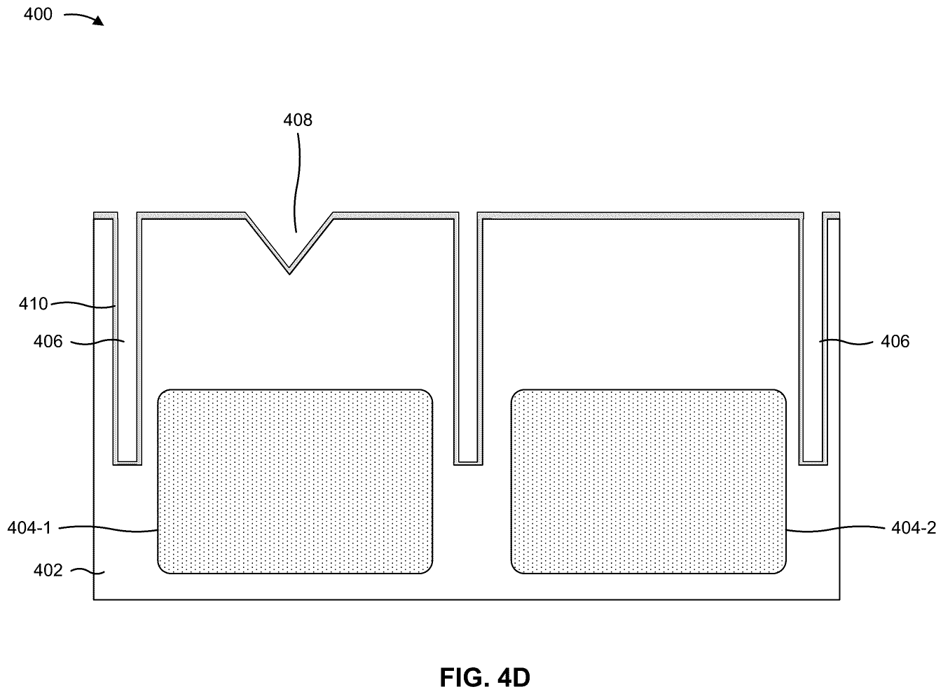

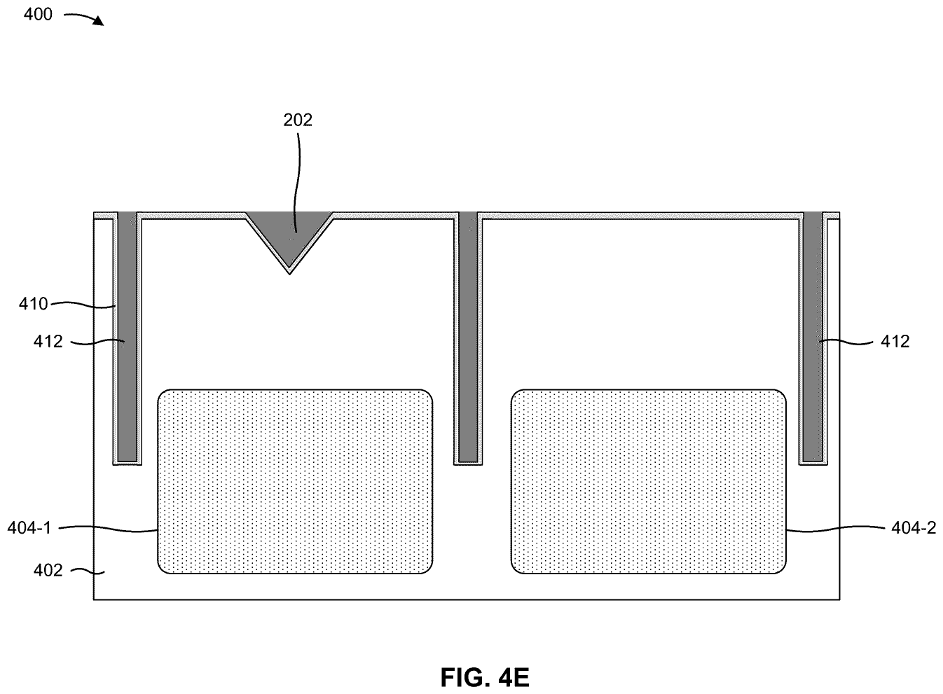

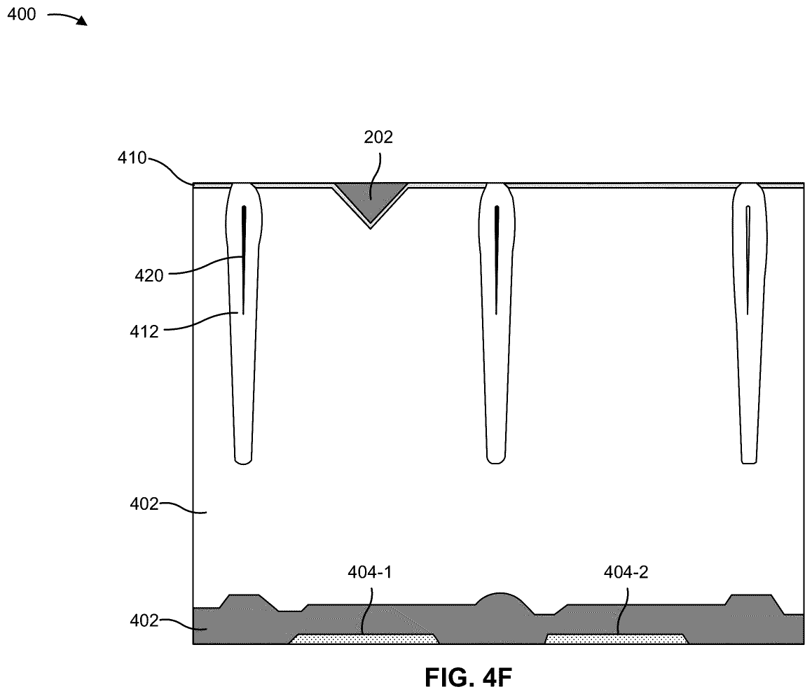

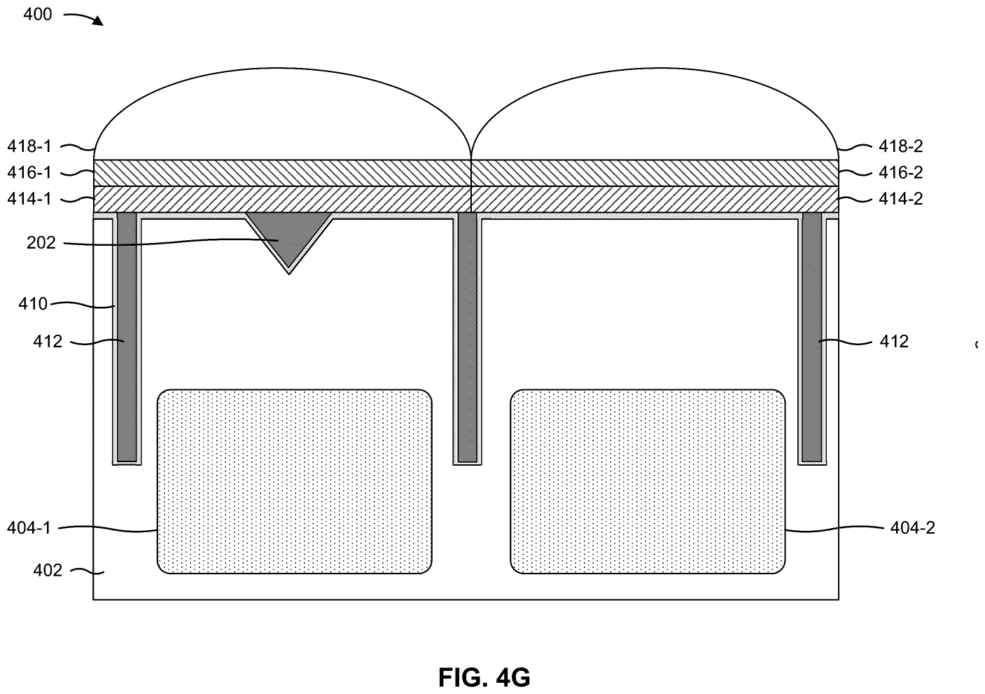

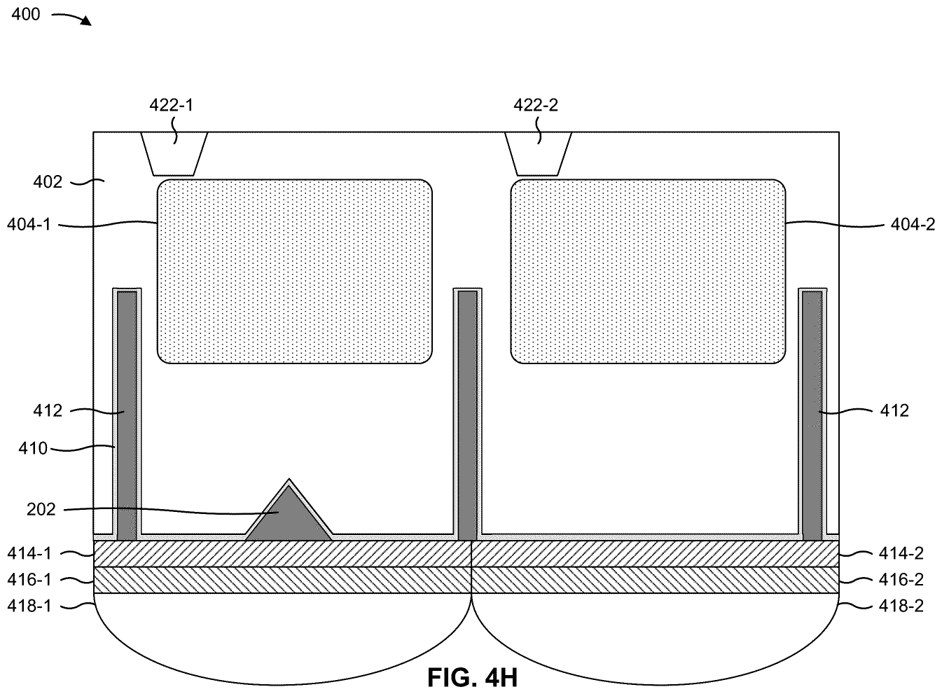

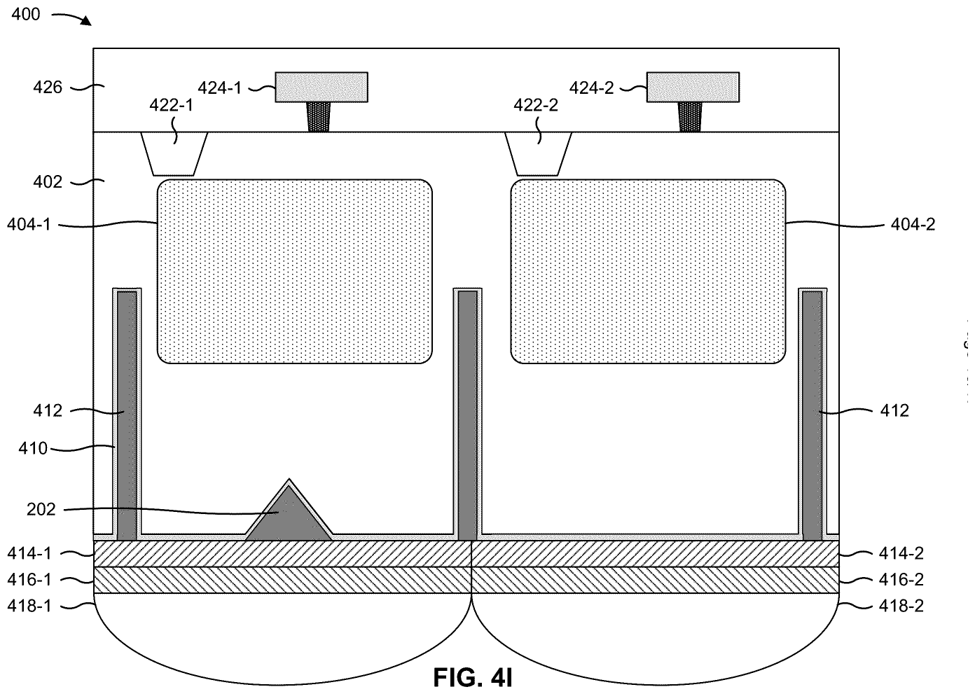

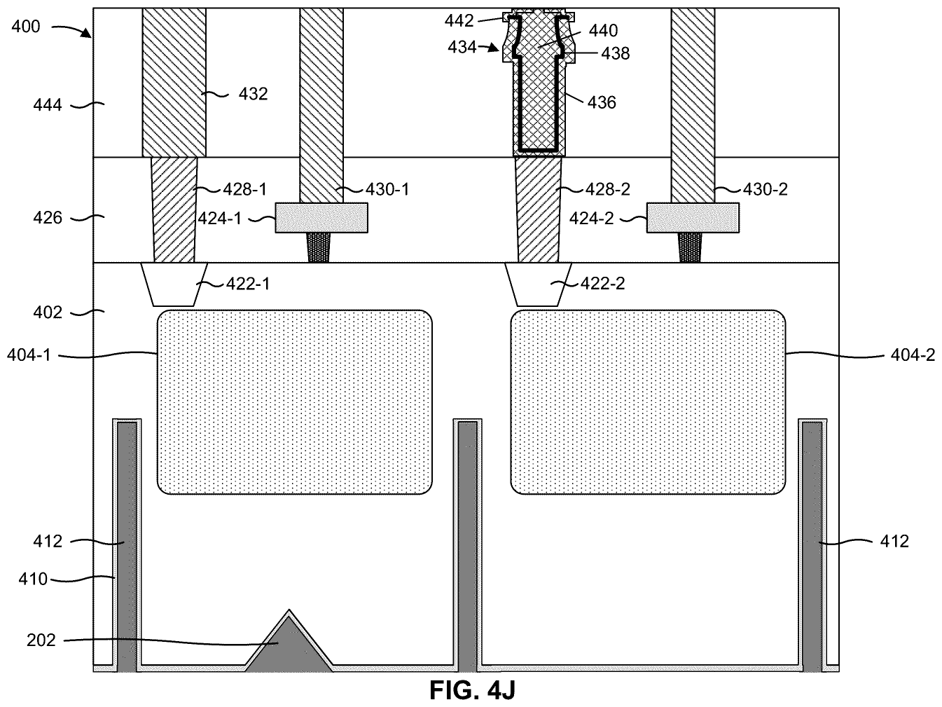

As indicated above, FIG. 1 is provided as an example. Other examples may differ from what is described with regard to FIG. 1. For example, the pixel sensors 102 may be electrically and optically isolated by an isolation structure (e.g., as described in connection with FIGS. 4A-4J), such as a deep trench isolation (DTI) structure. The isolation structure may include a plurality of interconnected trenches that are filled with a dielectric material, such as an oxide material. The trenches of the isolation structure may be included around the perimeters of the pixel sensors 102 such that the isolation structure surrounds the pixel sensors 102. Moreover, the trenches of the isolation structure may extend into a substrate in which the pixel sensors 102 are formed to surround the photodiodes and other structures of the pixel sensors 102 in the substrate. In some implementations, the isolation structure includes a back side DTI (BDTI) structure with a high aspect ratio that is formed from the back side of the pixel array 100.

FIG. 2A is a diagram of a pixel array 200. The pixel array 200 includes a first pixel sensor 102a that is associated with a photodiode (below a top surface of the first pixel sensor 102a) and has an HA structure 202. The HA structure 202 may have a cross-section (e.g., in the top-down view) that is approximately square. As used herein, “square” refers to a polygon that has four approximately equal sides (e.g., within 1%, 10%, or a similar margin of error). Additionally, the HA structure 202 may be a structure having angled walls such that the structure has an approximately pyramidal shape (e.g., exhibiting an approximately triangular shape in a cross-sectional view, as shown in FIGS. 4E and 4J, and an approximately polygonal shape in a top-down view, such as an approximately rectangular shape, as shown in FIG. 2A, or an approximately triangular shape). As used herein, “pyramidal shape” refers to a structure with a polygonal base connected to a point or to a smaller polygon that functions as an apex.

The HA structure 202 increases a quantum efficiency (QE) of the photodiode of the first pixel sensor 102a for NIR light (e.g., light near an 850 nanometer (nm) wavelength). For example, the first pixel sensor 102a may have a QE of more than 50% (e.g., approximately 60%) for NIR light.

As further shown in FIG. 2A, the pixel array 200 includes a second pixel sensor 102b that is associated with a photodiode (below a top surface of the second pixel sensor 102b) and is without an HA structure. The lack of an HA structure reduces a QE of the photodiode of the second pixel sensor 102b for NIR light. For example, the second pixel sensor 102b may have a QE of less than 50% (e.g., approximately 45%) for NIR light.

The first pixel sensor 102a and the second pixel sensor 102b thus have different capture rates. Therefore, a higher dynamic range is achieved by combining signals from the first pixel sensor 102a and the second pixel sensor 102b. For example, the pixel array 200 may achieve a dynamic range of approximately 140 dB or higher due to its increased capacity. Additionally, the pixel array 200 exhibits better dark performance as compared to a pixel array with a combination of LPDs and SPDs. Because each photodiode in the pixel array 200 is approximately a same size (e.g., within 1%, 10%, or a similar margin of error), photodiode leakage is reduced as compared with irregular pixel arrays including a combination of LPDs and SPDs.

As further shown in FIG. 2A, the second pixel sensor 102b may be connected to an LOFIC 204. The LOFIC 204 may be a metal-insulator-metal (MIM) structure formed in a BEOL region that connects to the pixel sensor 102b. An exposure time associated with the pixel sensor 102b is further increased by the LOFIC 204. As a result, a total signal achieved is larger and thus results in an even larger dynamic range for the pixel array 200.

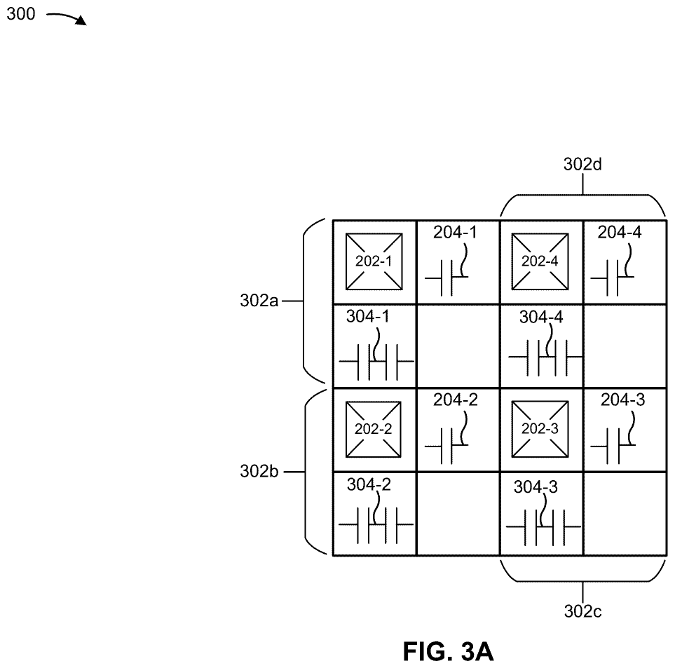

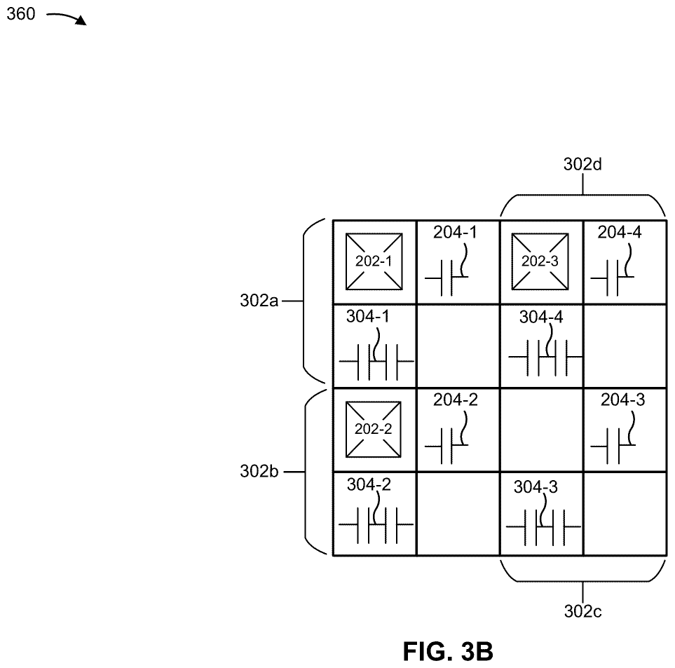

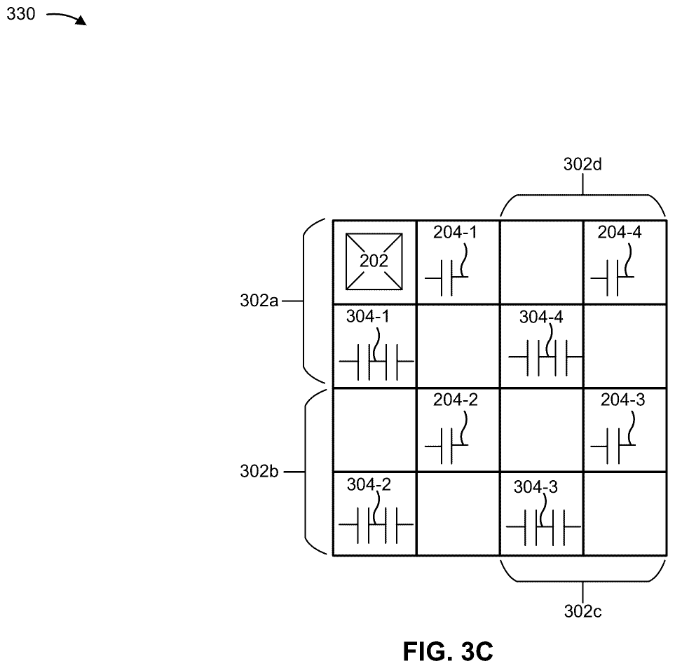

As indicated above, FIG. 2A is provided as an example. Other examples may differ from what is described with regard to FIG. 2A. For example, although the pixel array 200 is shown with a ratio of pixel sensors with HA structures to pixel sensors without HA structures of 1:1, other pixel arrays may include a larger ratio (e.g., more pixel sensors with HA structures than pixel sensors without HA structures) or a smaller ratio (e.g., as described in connection with FIGS. 3A-3C).

FIG. 2B is a diagram of example range graph 250 described herein. The example range graph 250 is shown with reference to example pixel array 200 of FIG. 2A. As shown in FIG. 2B, a total capacity of the pixel array 200 is increased because an exposure time associated with the pixel sensor 102b follows an exposure time associated with the pixel sensor 102a. Additionally, an exposure time associated with the pixel sensor 102b is further increased by the LOFIC 204. As a result, a total signal achieved is larger and thus results in a larger dynamic range for the pixel array 200.

As indicated above, FIG. 2B is provided as an example. Other examples may differ from what is described with regard to FIG. 2B. For example, although the pixel array 200 is shown with the LOFIC 204, other pixel arrays may omit the LOFIC or include multiple LOFICs (e.g., as described in connection with FIGS. 3A-3C).

FIG. 3A is a diagram of a pixel array 300. The pixel array 300 includes a first region 302a that includes four pixel sensors. The first region 302a includes one pixel sensor with an HA structure 202-1 and three pixel sensors without HA structures. Although the first region 302a is shown with a ratio of pixel sensors with HA structures to pixel sensors without HA 0107-0329 structures of 1:3, other regions may include a larger ratio (e.g., more pixel sensors with HA structures) or a smaller ratio (e.g., fewer pixel sensors with HA structures). A higher dynamic range is achieved by combining signals from the pixel sensor with the HA structure 202-1 and the pixel sensors without the HA structures. As further shown in FIG. 3A, the first region 302a includes a pixel sensor connected to an LOFIC 204-1 and a pixel sensor connected to a series of LOFICs 304-1 (e.g., two or more LOFICs connected in series). Exposure times are increased by the LOFIC 204-1 and the series of LOFICs 304-1. As a result, a total signal achieved is larger and thus results in an even larger dynamic range for the pixel array 300.

The pixel array 300 similarly includes a second region 302b having one pixel sensor with an HA structure 202-2 and three pixel sensors without HA structures. The second region 302b further includes a pixel sensor connected to an LOFIC 204-2 and a pixel sensor connected to a series of LOFICs 304-2. The pixel array 300 also includes a third region 302c having one pixel sensor with an HA structure 202-3 and three pixel sensors without HA structures. The third region 302c further includes a pixel sensor connected to an LOFIC 204-3 and a pixel sensor connected to a series of LOFICs 304-3. As further shown in FIG. 3A, the pixel array 300 includes a fourth region 302d having one pixel sensor with an HA structure 202-4 and three pixel sensors without HA structures. The fourth region 302d further includes a pixel sensor connected to an LOFIC 204-4 and a pixel sensor connected to a series of LOFICs 304-4. Each region may be associated with a different color filter. For example, the first region 302a may be associated with a red color filter (e.g., permitting a component of incident light near a 650 nm wavelength to pass and blocking other wavelengths from passing), the second region 302b and the fourth region 302d may be associated with a green color filter (e.g., permitting a component of incident light near a 550 nm wavelength to pass and blocking other wavelengths from passing), and the third region 302c may be associated with a blue color filter (e.g., permitting a component of incident light near a 450 nm wavelength to pass and blocking other wavelengths from passing). As a result, the dynamic range may be increased for NIR light even in a pixel array configured for visible light. Other color filters that may be used include a yellow color filter (e.g., permitting a component of incident light near a 580 nm wavelength to pass and blocking other wavelengths from passing), a white color filter (e.g., a non-discriminating or non-filtering region including a material that permits all wavelengths of light to pass), or an NIR color filter (e.g., including a material that permits a portion of incident light in an NIR wavelength range to pass while blocking visible light from passing).

FIG. 3B is a diagram of a pixel array 330. The pixel array 330 of FIG. 3B is similar to the pixel array 300 of FIG. 3A except that the third region 302c includes only pixel sensors that lack HA structures. For example, the third region 302c may be associated with a color filter that is more likely to filter NIR light (e.g., a blue color filter, as compared with green, yellow, or red color filters). As a result, power, processing resources, and raw materials are conserved that otherwise would have been expended in forming HA structures on pixel sensors that are less likely to absorb NIR light anyway.

FIG. 3C is a diagram of a pixel array 360. The pixel array 360 of FIG. 3C is similar to the pixel array 300 of FIG. 3A but includes an HA structure 202 only in a pixel sensor of the first region 302a. The other regions 302b, 302c, and 302d include only pixel sensors that lack HA structures. For example, the regions 302b, 302c, and 302d may be associated with color filters that are more likely to filter NIR light (e.g., green color filters or blue color filters, as compared with yellow color filters or red color filters). As a result, power, processing resources, and raw materials are conserved that otherwise would have been expended in forming HA structures on pixel sensors that are less likely to absorb NIR light anyway.

The pixel arrays 300, 330, and 360 exhibit better dark performance as compared to a pixel array with a combination of LPDs and SPDs. Because each pixel sensor in the pixel arrays 300, 330, and 360 is approximately a same size (e.g., within 1%, 10%, or a similar margin of error), photodiode leakage is reduced as compared with irregular pixel arrays including a combination of LPDs and SPDs.

As indicated above, FIGS. 3A-3C are provided as examples. Other examples may differ from what is described with regard to FIGS. 3A-3C. For example, other pixel arrays may include fewer regions (e.g., only three regions or two regions) or may include additional regions (e.g., associated with additional color filters). Additionally, or alternatively, each region may include fewer pixel sensors (e.g., one three pixel sensors or two pixel sensors) or may include additional pixel sensors.

FIGS. 4A-4J are diagrams of an example implementation 400 described herein. Example implementation 400 may be an example process for forming the pixel array 200 combining pixel sensors with HA structures with pixel sensors without HA structures. The pixel array formed using example implementation 400 may be included in a CMOS image sensor, a BSI CMOS image sensor, or another type of image sensor.

As shown in FIG. 4A, the example process for forming the pixel array may be performed in connection with a substrate 402. The substrate 402 may include a semiconductor die substrate, a semiconductor wafer, a stacked semiconductor wafer, or another type of substrate in which semiconductor pixels may be formed. For example, the substrate 402 may be formed of silicon (Si) (e.g., a silicon substrate), a material including silicon, a III-V compound semiconductor material such as gallium arsenide (GaAs), a silicon on insulator (SOI), or another type of semiconductor material that is capable of generating a charge from photons of incident light. In some implementations, the substrate 402 is formed of a doped material (e.g., a p-doped material or an n-doped material) such as a doped silicon.

As shown in FIG. 4B, a first photodiode 404-1 and a second photodiode 404-2 may be formed in the substrate 402. For example, an ion implantation tool may dope one or more portions of the substrate 402, using an ion implantation technique, to form n-type regions and/or p-type regions of the photodiodes 404-1 and 404-2 to form p-n junctions for the photodiodes 404-1 and 404-2. For example, an ion implantation tool may dope the substrate 402 with an n-type dopant to form n-type regions and may dope the substrate 402 with a p-type dopant to form p-type portions of the p-n junctions. In some implementations, another technique is used to form the photodiodes 404-1 and 404-2, such as diffusion.

As shown in FIG. 4C, an etch tool may form a trench 406 in the substrate 402 and at least partially surrounding the photodiodes 404-1 and 404-2. In some implementations, a deposition tool may form a photoresist layer over and/or on the frontside surface of the substrate 402, an exposure tool may expose the photoresist layer to a radiation source to form a pattern on the photoresist layer, and a developer tool may develop and remove portions of the photoresist layer to expose the pattern. Accordingly, an etch tool may etch a portion of the substrate 402 adjacent to the photodiodes 404-1 and 404-2. For example, an etch tool may use a wet etch technique, a dry etch technique, a plasma-enhanced etch technique, and/or another type of etch technique to etch the portion of the substrate 402. A photoresist removal tool may remove the remaining portions of the photoresist layer (e.g., using a chemical stripper, a plasma asher, and/or another technique) after the substrate 402 is etched.

As shown in FIG. 4C, the trench 406 may be approximately symmetric. As used herein, “approximately symmetric” refers to each section of the trench 406, adjacent to a photodiode, being approximately a same size (e.g., within 1%, 10%, or a similar margin of error) as other sections of the trench 406. Additionally, as shown in FIG. 4C, an etch tool may form a recess 408 in the substrate 402 over the first photodiode 404-1 (and without forming a recess over the second photodiode 404-2). The recess 408 may be approximately pyramidical (e.g., for an HA structure, as described in connection with FIG. 4E). In some implementations, a pattern exposed by a developer tool may also allow for an etch tool to form the recess 408 in addition to the trench 406. Alternatively, the recess 408 may be formed using a different etch cycle than the trench 406.

As shown in FIG. 4D, a lining layer 410 may be formed over the substrate 402. For example, a deposition tool may form the lining layer 410 over and/or on the frontside surface of the substrate 402 (and thus on bottom surfaces and sidewalls of the trench 406 and the recess 408). In some implementations, a deposition tool may form the lining layer 410 using a spin-coating technique, a chemical vapor deposition (CVD) technique, a physical vapor deposition (PVD) technique, an atomic layer deposition (ALD) technique, and/or another deposition technique. Some implementations may include a different material deposited in the recess 408 as compared with the trench 406.

As shown in FIG. 4E, the recess 408 and the trench 406 may be filled with dielectric material to form the HA structure 202 and the isolation structure 412, respectively. A deposition tool may deposit the dielectric material using a spin-coating technique, a CVD technique, a PVD technique, an ALD technique, and/or another deposition technique. In some implementations, the dielectric material may overflow the recess 408 and the trench 406 such that a planarization tool removes dielectric material outside of the recess 408 and the trench 406 using a chemical mechanical planarization (CMP) technique. Some implementations may include a different material used to form the HA structure 202 as compared with the isolation structure 412.

Although the example implementation 400 is shown with the HA structure 202 and the isolation structure 412 being formed together, other implementations may include the isolation structure 412 being formed before the recess 408 is formed and/or filled or may include the HA structure 202 being formed before the trench 406 is formed and/or filled.

FIG. 4F shows an alternate view of the structure formed according to the example implementation 400. In FIG. 4F, the HA structure 202 includes the lining layer 410, and the isolation structure 412 lacks the lining layer 410. The lining layer 410 for the HA structure 202 may be a same lining layer as used in the isolation structure 412 (e.g., an antireflective coating (ARC) that includes a suitable material for reducing a reflection of incident light, such as a nitrogen-containing material) or may be a different lining layer (e.g., a passivation layer to protect the substrate 402 during deposition of the dielectric material to form the HA structure 202.

As further shown in FIG. 4F, the isolation structure 412 is rough rather than precisely rectangular. Additionally, the isolation structure 412 further includes voids 420 in each trench in order to further reduce crosstalk between adjacent pixel sensors. Furthermore, the photodiodes 404-1 and 404-2 may have a depth, relative to a top surface of the substrate 402, that is larger than a depth of the isolation structure 412 relative to the top surface of the substrate 402. As a result, the photodiodes 404-1 and 404-2 may remain undamaged during formation of the isolation structure 412.

As shown in FIG. 4G, a buffer layer 414-1 may be formed on a top surface of the substrate 402 over the first photodiode 404-1, and a buffer layer 414-2 may be formed on the top surface of the substrate 402 over the second photodiode 404-2. A deposition tool may deposit the buffer layers 414-1 and 414-2 using a CVD technique, a PVD technique, an ALD technique, or another type of deposition technique. A planarization tool may planarize the buffer layers 414-1 and 414-2 after deposition.

Additionally, as shown in FIG. 4G, a color filter 416-1 may be formed on the top surface of the substrate 402 over the first photodiode 404-1, and a color filter 416-2 may be formed on the top surface of the substrate 402 over the second photodiode 404-2. A deposition tool may deposit the color filters 416-1 and 416-2 using a CVD technique, a PVD technique, an ALD technique, or another type of deposition technique. A planarization tool may planarize the color filters 416-1 and 416-2 after deposition. When the photodiodes 404-1 and 404-2 are associated with a same region of the pixel array (e.g., as described in connection with FIGS. 3A-3B), the color filters 416-1 and 416-2 may be configured for a same color. When the photodiodes 404-1 and 404-2 are associated with different regions of the pixel array (e.g., as described in connection with FIGS. 3A-3B), the color filters 416-1 and 416-2 may be configured for different colors.

As further shown in FIG. 4G, a micro-lens 418-1 may be formed on the top surface of the substrate 402 over the first photodiode 404-1, and a micro-lens 418-2 may be formed on the top surface of the substrate 402 over the second photodiode 404-2. A deposition tool may deposit the micro-lenses 418-1 and 418-2 using a CVD technique, a PVD technique, an ALD technique, or another type of deposition technique. In some implementations, the photodiodes 404-1 and 404-2 may share a micro-lens rather than being associated with different micro-lenses (e.g., when the photodiodes 404-1 and 404-2 are associated with a same region of the pixel array, as described in connection with FIGS. 3A-3B).

As shown in FIG. 4H, a first floating diffusion (FD) node 422-1 may be provided for the first photodiode 404-1, and a second FD node 422-2 may be provided for the first photodiode 404-2. The FD nodes 422-1 and 422-2 may each include a drain region, such as a highly-doped n-type region (e.g., an n⁺ doped region). The photodiodes 404-1 and 404-2 thus generate photocurrent that flows from the photodiodes 404-1 and 404-2 to the corresponding FD nodes 422-1 and 422-2, respectively. Although the example implementation 400 is shown with a corresponding FD node for each photodiode, other examples may include the photodiodes 404-1 and 404-2 sharing an FD node.

As shown in FIG. 4I, a first transfer (TX) gate 424-1 may be provided for the first photodiode 404-1 to control the transfer of photocurrent between the photodiode 404-1 and the FD node 422-1. Similarly, a second TX gate 424-2 may be provided for the second photodiode 404-2 to control the transfer of photocurrent between the photodiode 404-2 and the FD node 422-2. The TX gates 424-1 and 424-2 may be energized (e.g., by applying a voltage or a current to the TX gates 424-1 and 424-2) to cause conductive channels to form between the photodiodes 404-1 and 404-2 and the corresponding FD nodes 422-1 and 422-2, respectively. The conductive channels may be removed or closed by de-energizing the TX gates 424-1 and 424-2, which blocks and/or prevents the flow of photocurrent between the photodiodes 404-1 and 404-2 and the corresponding FD nodes 422-1 and 422-2, respectively. The TX gates 424-1 and 424-2 may be included in one or more dielectric layers 426.

As shown in FIG. 4J, contact structures 428-1 and 428-2 may be formed to contact the FD nodes 422-1 and 422-2, respectively. The contact structures 428-1 and 428-2 may connect the FD nodes 422-1 and 422-2 to a BEOL metallization stack. Additionally, contact structures 430-1 and 430-2 may be formed to contact the TX gates 424-1 and 424-2, respectively. The contact structures 430-1 and 430-2 may connect the TX gates 424-1 and 424-2 to a control circuit (e.g., for controlling the flow of photocurrent, as described above).

As further shown in FIG. 4J, contact structure 428-1 connects the FD node 422-1 to a metallization layer 432. The metallization layer 432 may include tungsten (W), cobalt (Co), ruthenium (Ru), titanium (Ti), aluminum (Al), copper (Cu), and/or gold (Au), among other examples of conductive materials. On the other hand, the contact structure 428-2 connects the FD node 422-2 to an LOFIC, which is a metal-insulator-metal (MIM) capacitor 434 in the example implementation 400. Therefore, the photodiode 404-1 is associated with the HA structure 202 while the photodiode 404-2 is associated with the LOFIC, as described in connection with FIG. 2A. In some implementations, the MIM capacitor 434 may be located further into the BEOL and/or may be formed in series with another MIM capacitor (e.g., as described in connection with FIGS. 3A-3C).

The MIM capacitor 434 may include a first metal 436, an insulator 438, and a second metal 440. The first metal 436 and the second metal 440 may correspond to the conductive electrode layers of the MIM capacitor 434. The first metal 436 may be referred to as the capacitor bottom metal (CBM) layer, and the second metal 440 may be referred to as the capacitor top metal (CTM) layer. The insulator 438 may be located between the first metal 436 and the second metal 440. The first metal 436 and the second metal 440 may each include one or more electrically conductive materials. Examples include metals like tungsten (W), cobalt (Co), ruthenium (Ru), titanium (Ti), aluminum (Al), copper (Cu), or gold (Au), and metal nitrides like titanium nitride (TiN) or tantalum nitride (TaN), among other examples. The insulator 438 may include one or more electrically insulating and/or dielectric materials. In some implementations, the insulator 438 includes one or more dielectric materials having a relatively high dielectric constant (also referred to as a “high-κ material”), such as a dielectric constant greater relative to the dielectric constant of silicon dioxide (SiO₂).

In some implementations, a capping layer 442 may be included over the top of the MIM capacitor 434. The capping layer 442 may electrically isolate the MIM capacitor 434 from other structures. Additionally and/or alternatively, the capping layer 442 may function as a hard mask layer and/or an etch stop layer during manufacturing of the MIM capacitor 434.

The contact structures 428-1 and 428-2 may be included in the dielectric layer(s) 426. Additionally, the metallization layer 432 and the MIM capacitor 434 may be included in one or more dielectric layers 444. In the example implementation 400, the contact structures 430-1 and 430-2 are formed across the dielectric layer(s) 426 and the dielectric layer(s) 444. Other implementations may include the contact structures 430-1 and 430-2 in a single dielectric layer (or a single stack of dielectric layers).

As indicated above, FIGS. 4A-4J are provided as an example. Other examples may differ from what is described with regard to FIGS. 4A-4J. For example, although the example implementation 400 is shown with two photodiodes, other implementations may include additional photodiodes being formed (e.g., to fabricate pixel arrays as described in connection with FIGS. 3A-3C).

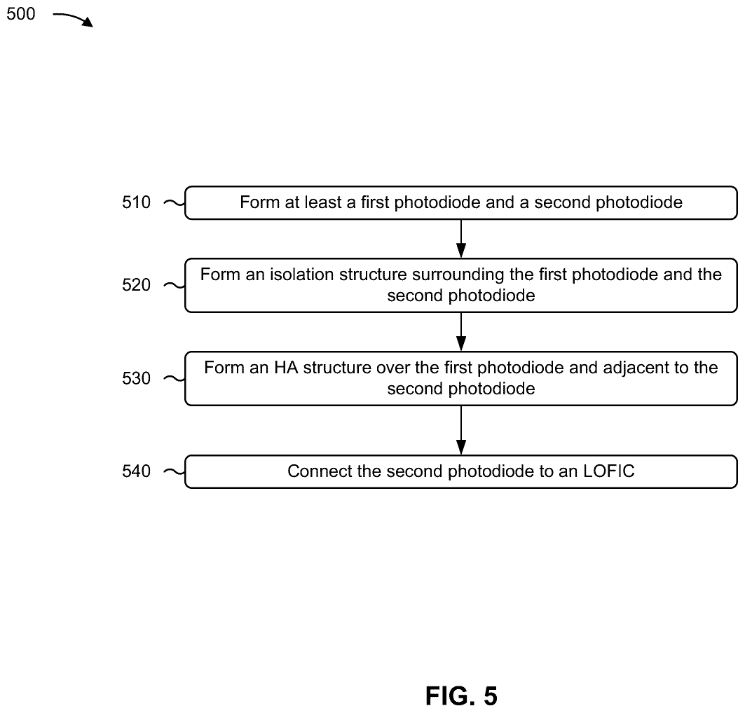

FIG. 5 is a flowchart of an example process 500 associated with forming a pixel array described herein. In some implementations, one or more process blocks of FIG. 5 are performed using one or more semiconductor processing tools. Additionally, or alternatively, one or more process blocks of FIG. 5 may be performed using one or more components of a device, such as a processor, a memory, an input component, an output component, and/or a communication component.

As shown in FIG. 5, process 500 may include forming at least a first photodiode and a second photodiode (block 510). For example, one or more of the semiconductor processing tools may be used to form at least a first photodiode 404-1 and a second photodiode 404-2, as described herein.

As further shown in FIG. 5, process 500 may include forming an isolation structure surrounding the first photodiode and the second photodiode (block 520). For example, one or more of the semiconductor processing tools may be used to form an isolation structure 412 surrounding the first photodiode 401-1 and the second photodiode 404-2, as described herein.

As further shown in FIG. 5, process 500 may include forming an HA structure over the first photodiode and adjacent to the second photodiode (block 530). For example, one or more of the semiconductor processing tools may be used to form an HA structure 202 over the first photodiode 404-1 and adjacent to the second photodiode 401-2, as described herein.

As further shown in FIG. 5, process 500 may include connecting the second photodiode to an LOFIC (block 540). For example, one or more of the semiconductor processing tools may be used to connect the second photodiode 404-2 to an LOFIC 204, as described herein.

Process 500 may include additional implementations, such as any single implementation or any combination of implementations described below and/or in connection with one or more other processes described elsewhere herein.

In a first implementation, process 500 includes forming a color filter 416 over the first photodiode 404-1 and the second photodiode 404-2.

In a second implementation, alone or in combination with the first implementation, process 500 includes forming an additional LOFIC in series with the LOFIC 204.

In a third implementation, alone or in combination with one or more of the first and second implementations, process 500 includes forming the LOFIC 204 by depositing a first metal layer, an insulator layer, and a second metal layer.

In a fourth implementation, alone or in combination with one or more of the first through third implementations, forming the isolation structure 412 includes forming a trench 406 that surrounds the first photodiode 404-1 and the second photodiode 401-2 and that is approximately symmetric, and filling the trench 406 with at least one dielectric material to form the isolation structure 412.

In a fifth implementation, alone or in combination with one or more of the first through fourth implementations, forming the HA structure 202 includes forming a recess 408 that is approximately pyramidal, and filling the recess 408 with at least one dielectric material to form the HA structure 202.

In a sixth implementation, alone or in combination with one or more of the first through fifth implementations, process 500 includes forming a third photodiode, and connecting the third photodiode to a series of LOFICs.

In a seventh implementation, alone or in combination with one or more of the first through sixth implementations, process 500 includes connecting the second photodiode 404-2 to a BEOL, where the BEOL includes the LOFIC 204.

Although FIG. 5 shows example blocks of process 500, in some implementations, process 500 includes additional blocks, fewer blocks, different blocks, or differently arranged blocks than those depicted in FIG. 5. Additionally, or alternatively, two or more of the blocks of process 500 may be performed in parallel.

In this way, a pixel array that includes some pixels with HA structures and other pixels without HA structures exhibits increased dynamic range for NIR light. Additionally, the pixel array is a uniform array of photodiodes and thus does not exhibit current leakage that would have been caused by irregular isolation structures. Additionally, the pixel array may further include an LOFIC to further increase the dynamic range for NIR light.

As described in greater detail above, some implementations described herein provide a semiconductor structure. The semiconductor structure includes a first pixel sensor including a high absorption (HA) structure. The semiconductor structure includes a second pixel sensor without an HA structure and connected to a lateral overflow integration capacitor (LOFIC).

As described in greater detail above, some implementations described herein provide a method. The method includes forming at least a first photodiode and a second photodiode. The method includes forming an isolation structure surrounding the first photodiode and the second photodiode. The method includes forming a high absorption (HA) structure over the first photodiode and adjacent to the second photodiode. The method includes connecting the second photodiode to a lateral overflow integration capacitor (LOFIC).

As described in greater detail above, some implementations described herein provide a pixel array. The pixel array includes a first region associated with a first color filter. The first region includes a first pixel including a high absorption (HA) structure and a second pixel without an HA structure and connected to a lateral overflow integration capacitor (LOFIC). The pixel array includes a second region associated with a second color filter. The second region includes a plurality of pixels without HA structures and connected to an LOFIC.

As used herein, “satisfying a threshold” may, depending on the context, refer to a value being greater than the threshold, greater than or equal to the threshold, less than the threshold, less than or equal to the threshold, equal to the threshold, not equal to the threshold, or the like.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a first pixel sensor including a high absorption (HA) structure; and
a second pixel sensor without an HA structure and connected to a lateral overflow integration capacitor (LOFIC).

2. The semiconductor structure of claim 1, wherein the first pixel sensor is associated with a quantum efficiency (QE) of more than 50%, and the second pixel sensor is associated with a QE of less than 50%.

3. The semiconductor structure of claim 1, wherein the LOFIC comprises a metal-insulator-metal (MIM) structure.

4. The semiconductor structure of claim 1, further comprising:
an additional LOFIC connected in series with the LOFIC.

5. The semiconductor structure of claim 1, wherein the first pixel sensor is approximately a same size as the second pixel sensor.

6. The semiconductor structure of claim 1, wherein the HA structure is approximately pyramidal.

7. A method, comprising:
forming at least a first photodiode and a second photodiode;
forming an isolation structure surrounding the first photodiode and the second photodiode;
forming a high absorption (HA) structure over the first photodiode and adjacent to the second photodiode; and
connecting the second photodiode to a lateral overflow integration capacitor (LOFIC).

8. The method of claim 7, further comprising:
forming a color filter over the first photodiode and the second photodiode.

9. The method of claim 7, further comprising:
forming an additional LOFIC in series with the LOFIC.

10. The method of claim 7, further comprising:
forming the LOFIC by depositing a first metal layer, an insulator layer, and a second metal layer.

11. The method of claim 7, wherein forming the isolation structure comprises:
forming a trench that surrounds the first photodiode and the second photodiode and that is approximately symmetric; and
filling the trench with at least one dielectric material to form the isolation structure.

12. The method of claim 7, wherein forming the HA structure comprises:
forming a recess that is approximately pyramidal; and
filling the recess with at least one dielectric material to form the HA structure.

13. The method of claim 7, further comprising:
forming a third photodiode; and
connecting the third photodiode to a series of LOFICs.

14. The method of claim 7, further comprising:
connecting the second photodiode to a back end of line (BEOL),
wherein the BEOL includes the LOFIC.

15. A pixel array, comprising:
a first region associated with a first color filter, comprising:
a first pixel including a high absorption (HA) structure; and
a second pixel without an HA structure and connected to a lateral overflow integration capacitor (LOFIC); and
a second region associated with a second color filter, comprising:
a plurality of pixels without HA structures and connected to an LOFIC.

16. The pixel array of claim 15, wherein the first color filter comprises a red filter or a green filter.

17. The pixel array of claim 15, wherein the second color filter comprises a blue filter or a green filter.

18. The pixel array of claim 15, further comprising:
a third pixel in the first region, without an HA structure and connected to a series of two LOFICs.

19. The pixel array of claim 15, further comprising:
an additional pixel in the second region, without an HA structure and connected to a series of two LOFICs.

20. The pixel array of claim 15, wherein the first region is approximately a same size as the second region.
